(19) United States
(12) Patent Application Publication
(10) Pub. No.: US 2019/0059165 A1
(43) Pub. Date: Feb. 21, 2019

(54) HANGER AND ELECTRIC APPLIANCE

(71) Applicant: Christian Gassner, Shenzhen (CN)

(72) Inventor: Christian Gassner, Shenzhen (CN)

(21) Appl. No.: 15/998,812

(22) Filed: Aug. 16, 2018

(30) Foreign Application Priority Data
Aug. 17, 2017 (CN) 201721034570.8

(51) Int. Cl. H05K 5/02

(52) U.S. Cl. CPC H05K 5/0204; H05K 5/0217

(57) ABSTRACT

A hanger for holding a power adapter, the hanger comprises a hanging plate for fixed connection with an external object, and two side plates connected to the hanging plate and extending in the same direction at the two side edges of the hanging plate respectively, the two side plates are oppositely disposed, and the hanging plate and the two side plates are collectively enclosed to form an accommodating space for accommodating the power adapter; the two side plates are respectively provided with convex portions on the surface facing the accommodating space to form a strip-shaped clasping portion press-fitted with the power adapter, and surfaces of the two side plates are respectively provided with a concave portion corresponding to the position of the strip-shaped clasping portion facing away from the accommodating space. Which makes the power adapter safe to be use and has a long service life.

### CROSS-REFERENCES TO RELATED APPLICATIONS

This application claims the priority of Chinese patent application no. 201721034570.8, filed on Aug. 17, 2017, the entire contents of all of which are incorporated herein by reference.

### TECHNICAL FIELD

The present application relates to the field of electronic device, especially to a hanger and an electric appliance.

### BACKGROUND

The power adapter is a power supply conversion device for small portable electronic devices and electronic appliances. It is widely used in security cameras, set-top boxes, routers, light bars, liquid crystal displays, laptops, massage chairs, electric beds, medical beds and other electronic devices.

When using these electronic devices, the power adapter is connected between the mains power interface and the electronic device. After this connection, the power adapter is often placed on the ground or on the table near the electronic device at will. The power adapter placed in this way not only makes the working environment messy, but also reduces the service life of the power adapter because the ground is wet or accidentally hit, kicked, etc.; if there are other electronic devices or peripheral electronic circuits are more complicated beside the electronic device, and there is a risk of fire during the use of the power adapter.

### SUMMARY

An object of the present application is to provide a power adapter hanger, in order to solve the problem that the power adapter in the prior art cannot be fixed, is easily damaged by an external force, and affects the service life.

The present application is implemented as follows, a hanger for holding a power adapter, the hanger comprises a hanging plate for fixed connection with an external object, and two side plates connected to the hanging plate and extending outside from the same direction at the two side edges of the hanging plate respectively, with the two side plates being oppositely disposed, and the hanging plate and the two side plates are collectively enclosed to form an accommodating space for accommodating the power adapter; both of the two side plates are respectively provided with convex portions on the surface facing the accommodating space to form a strip-shaped clasping portion press-fitted with the power adapter, and surfaces of the two side plates facing away from the accommodating space are respectively provided with a concave portion corresponding to the position of the strip-shaped clasping portion.

Further, a plurality of through holes penetrating the accommodating space are respectively disposed on the surfaces of the two side plates, and the through holes are spaced apart along the extending direction of the strip-shaped clasping portion.

Further, the hanger comprises a guide plate connected to either of the side plates, the guide plate is connected to a side of the side plate, and the guide plate is facing away from the hanging plate, and the guide plate extends along the direction facing away from the hanging plate, and is obliquely disposed away from the accommodating space.

Further, the hanging plate is provided with a perforation for a fastener passing, and the number of the perforation is at least two.

Further, the hanging plate is provided with an accommodating groove facing toward a surface of the accommodating space, and the through hole is opened at a groove bottom of the accommodating groove.

Further, the accommodating groove penetrates to edges of the hanging plate.

Further, an electric appliance comprises the hanger, and the power adapter is held to the hanger.

Further, an end of the power adapter slides into and is limited into the accommodating space and is press-fitted with the strip-shaped clasping portion, and an end surface of the sliding-in end of the power adapter abuts against the hanging plate.

Further, the power adapter is provided with slots on its surfaces facing toward the side plate, and the strip-shaped clasping portion is engaged with the corresponding slot.

Further, the electric appliance is the one selected from a group consisting of a security camera, a set top box, a router, a light bar, a liquid crystal display, a laptop, a massage chair and an electric bed and a medical bed.

Compare to the prior art, the technical effect of the present application is: he hanger is fixed on the wall or a position that is not easily impacted by an external force, and then the power adapter to be used is inserted into the accommodating space, until the strip-shaped clasping portion is press-fitted with the power adapter, the power adapter and the hanger are fixed together at a predetermined safety position. In this way, not only the work site environment is clean and tidy, but also the impact of the external force on the power adapter is avoided, which makes the power adapter safe to be used, and has a long service life.

### BRIEF DESCRIPTION OF THE DRAWINGS

FIG. 1 is an assemble schematic view of a power adapter and a hanger provided by an embodiment of the present application;

FIG. 2 is a schematic structural view of the hanger of FIG. 1 provided by an embodiment of the present application;

FIG. 3 is a right side view of the hanger of FIG. 2;

FIG. 4 is a schematic structural view of the power adapter of FIG. 1 provided by an embodiment of the present application;

FIG. 5 is a right side view of FIG. 1.

The relationship between the reference numerals and the corresponding components in the drawing are as follow:
100 electric appliance, 24 through hole;
10 power adapter, 212 perforation;
20 hanger, 251 opening;
211 accommodating groove, 221 strip-shaped clasping portion;
21 hanging plate, 11 slot;
22 side plate, 25 accommodating space;
23 guide plate, 222 concave portion.

### DETAILED DESCRIPTION OF THE EMBODIMENTS

The embodiments of the present application are described in detail below, and the examples of the embodiments are illustrated in the drawings, wherein the same or similar reference numerals are used to refer to the same or similar components or components having the same or similar functions. The embodiments described below with reference to the drawings are intended to be illustrative of the present application and are not to be construed as limiting.

In the description of the present application, it is to be understood that the orientations or positional relationships indicated by the terms “thickness”, “upper”, “lower”, “vertical”, “parallel”, “bottom”, “angle”, etc. are based on the orientation or positional relationship shown in the drawings is merely for the convenience of the description of the present application and the simplified description, and is not intended to indicate or imply that the device or component referred to has a specific orientation, is constructed and operated in a specific orientation, and thus cannot be understood to limit the present application.

In the present application, the terms “installation”, “connection” and the like should be understood broadly, and may be, for example, a fixed connection, a detachable connection, or an integral; may also be a mechanical connection, an electrical connection; it may also be directly connected or indirectly connected through an intermediate medium, and may be an internal connection of two elements or an interaction relationship of two elements.

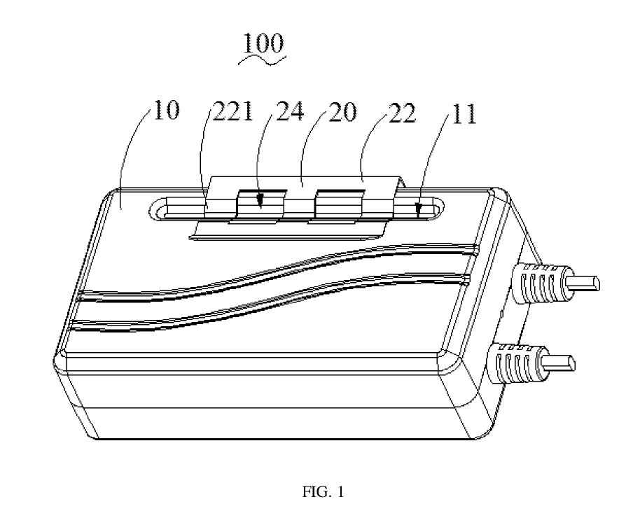

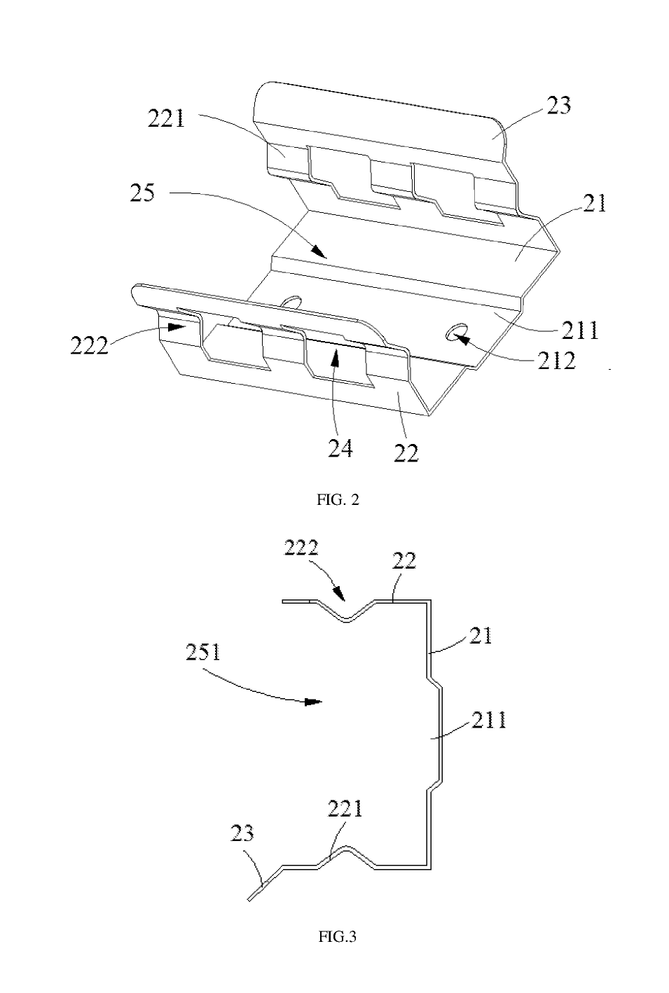

Please refer to FIG. 1 to FIG. 3, an electric appliance 100 according to an embodiment of the present application includes a power adapter 10 and a hanger 20 that holds the power adapter 10.

The hanger 20 includes a hanging plate 21 and two side plates 22, the two side plates 22 respectively extending outside from the same direction with two side edges of the hanging plate 21. The hanging plate 21 is provided with a plurality of perforations 212 for a fastener (not shown) passing. To ensure the fixing effect of the hanger 20, the number of the perforation 212 is at least two, and the number of the perforation 212 in the embodiment of the present application is two. The two oppositely disposed side plates 22 and the hanging plates 21 are collectively enclosed to form an accommodating space 25 for accommodating the power adapter 10. An end of the power adapter 10 slides into the accommodating space 25 from the opening 251 of the accommodating space 25 and is limited to the accommodating space 25.

The two side plates 22 are respectively provided with convex portions to form a strip-shaped clasping portion 221 press-fitting with the power adapter 10, and surfaces of the two side plates 22 are respectively provided with a concave portion 222 corresponding to the position of the strip-shaped clasping portion 221 facing away from the accommodating space 25.

A plurality of through holes 24 penetrating the accommodating spaces 25 are formed on the surfaces of the two side plates 22, and the through holes 24 are spaced apart along the extending direction of the strip-shaped clasping portions 221. The through holes 24 can reduce the material usage of the side plates 22, and save cost. The shape of the through hole 24 may be square, circular or elliptical, preferably, the shape of the through hole 24 in the present embodiment is square and the number of the through hole is two.

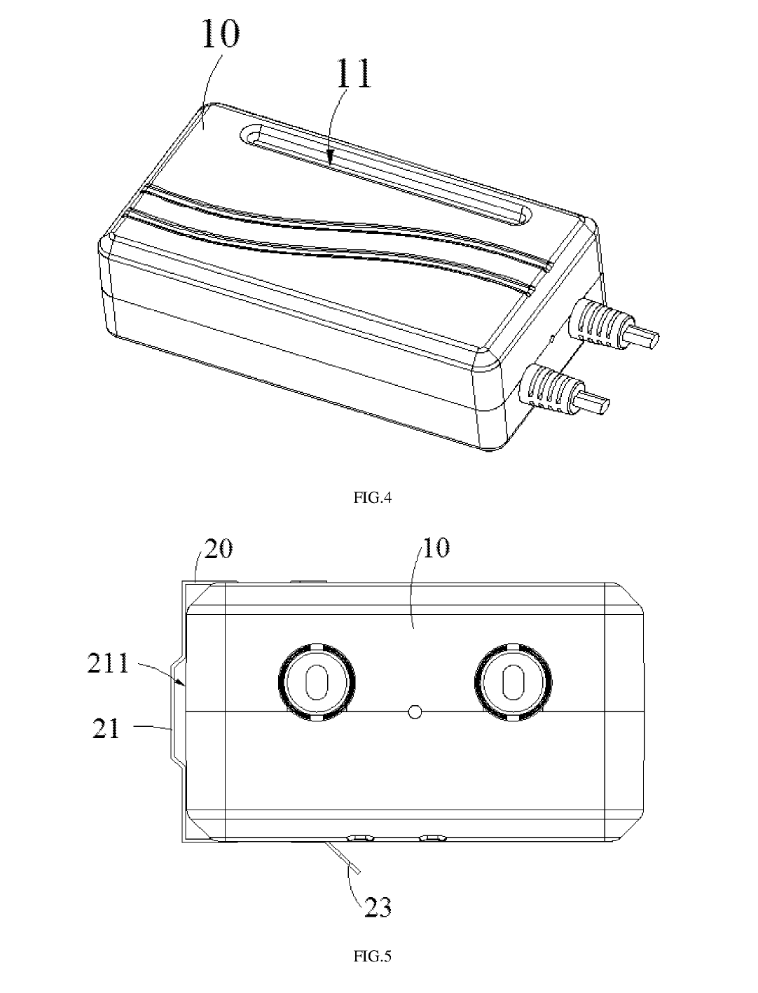

Please refer to FIG. 4 to FIG. 5 simultaneously, the strip-shaped clasping portions 221 of the two side plates 22 are convexly opposed to each other for clamping and limiting the power adapter 10 slid into the accommodating space 25. A slot 11 is disposed on the surfaces of the two side plates 22 facing toward the power adapter 10, and the strip-shaped clasping portions 221 are all clasped in the corresponding slots 11. Specifically, the strip-shaped clasping portions 221 on the two side plates 22 are engaged in the corresponding slots 11 and are pressed toward each other. Thus, the power adapter 10 is limited between the two side plates 22, and one end of the power adapter 10 sliding into the accommodating space 25 is fixed in the accommodating space 25, that is, the power adapter 10 is fixed on the hanger 20.

An accommodating groove 211 is disposed in the surface of the hanging plate 21 facing the accommodating space 25, and the perforations 212 are disposed at the groove bottom of the accommodating groove 211. The accommodating groove 211 penetrates to edges of the hanging plate 21. The fastener is disposed in the accommodating groove 211 to prevent the fastener from adversely affecting the appearance of the power adapter 10 and achieving the effect of the countersunk nut.

The hanger 20 comprises a guide plate 23 connected to either of the side plates 22, the guide plate 23 is connected to a side of the side plate 22 facing away from the hanging plate 21, the guide plate 23 extends along the direction facing away from the hanging plate 21, and is obliquely disposed away from the accommodating space 25.

Specifically, the guide plate 23 can not only guide the power adapter 10 to smoothly slide into the accommodating space 25, but also offer a assist in disassembly. When a pressure is applied to the surface of the guide plate 23 facing the accommodating space 25, the guide plate 23 and the side plate 22 connecting the guide plates 23 are displaced by the pressure, thereby making the opening 251 larger so that the power adapter 10 can be easily taken out.

The hanger 20 can be fixed to the wall, the table top, and a secure location that is not easily impacted by external forces via two perforations 212. An end of the power adapter 10 provided with the slot 11 is slid into the accommodating space 25 of the hanger 20 from the opening 251 by guiding of the guide plate 23, until the end surface of the end of the power adapter 10 is abutted with the hanging plate 21. At this time, the strip-shaped clasping portions 221 are respectively pressed into the corresponding slots 11, thereby limiting the power adapter 10 to the hanger 20.

Thus, the power adapter 10 is fixed at a predetermined safe position. Therefore, the work site environment is clean and tidy, and the impact of the external force on the power adapter 10 is avoided so that the power adapter 10 is safe to use and has a long service life.

The electric appliance 100 can be the one selected from a group consisting of a security camera, a set top box, a router, a light bar, a liquid crystal display, a laptop, a massage chair, an electric bed and a medical bed.

It's obvious that the aforementioned embodiments are only preferred embodiments of the present application, and are not intended to limit the present application. Any modification, equivalent replacement, improvement, and so on, which are made within the spirit and the principle of the present application, should be comprised in the scope of the present application.

What is claimed is:

1. A hanger for holding a power adapter, wherein the hanger comprising: a hanging plate for fixed connection with an external object, and two side plates connected to the hanging plate and extending outside from the same direction at the two side edges of the hanging plate respectively, with the two side plates being oppositely disposed, wherein the hanging plate and the two side plates are collectively enclosed to form an accommodating space for accommodating the power adapter; both of the two side plates are respectively provided with convex portions on the surface facing the accommodating space to form a strip-shaped clasping portion press-fitted with the power adapter, and surfaces of the two side plates facing away from the accommodating space are respectively provided with a concave portion corresponding to the position of the strip-shaped clasping portion.

2. The hanger of claim 1, wherein a plurality of through holes penetrating the accommodating space are respectively disposed on the surfaces of the two side plates, and the through holes are spaced apart in the extending direction of the strip-shaped clasping portion.

3. The hanger of claim 1, wherein the hanger comprising: a guide plate connected to either of the side plates, the guide plate is connected to a side edge of the side plate, and the guide plate is facing away from the hanging plate, the guide plate extends towards the direction facing away from the hanging plate, and is obliquely disposed in a direction away from the accommodating space.

4. The hanger of claim 1, wherein the hanging plate is provided with perforations for fasteners passing through, and the number of the perforation is at least two.

5. The hanger of claim 4, wherein the hanging plate is provided with an accommodating groove facing toward a surface of the accommodating space, wherein the perforations are formed in the bottom of the accommodating groove.

6. The hanger of claim 5, wherein the accommodating groove penetrates through to edges of the hanging plate.

7. An electric appliance, wherein the electric appliance comprising the power adapter and the hanger of claim 1, and the power adapter is held to the hanger.

8. An electric appliance, wherein the electric appliance comprising the power adapter and the hanger of claim 2, and the power adapter is held to the hanger.

9. An electric appliance, wherein the electric appliance comprising the power adapter and the hanger of claim 3, and the power adapter is held to the hanger.

10. An electric appliance, wherein the electric appliance comprising the power adapter and the hanger of claim 4, and the power adapter is held to the hanger.

11. An electric appliance, wherein the electric appliance comprising the power adapter and the hanger of claim 5, and the power adapter is held to the hanger.

12. An electric appliance, wherein the electric appliance comprising the power adapter and the hanger of claim 6, and the power adapter is held to the hanger.

13. The electric appliance of claim 7, wherein an end of the power adapter slides into and being limited into the accommodating space and is press-fitted with the strip-shaped clasping portion, and an end surface of the sliding-in end of the power adapter abuts against the hanging plate.

14. The electric appliance of claim 8, wherein an end of the power adapter slides into and being limited into the accommodating space and is press-fitted with the strip-shaped clasping portion, and an end surface of the sliding-in end of the power adapter abuts against the hanging plate.

15. The electric appliance of claim 9, wherein an end of the power adapter slides into and being limited into the accommodating space and is press-fitted with the strip-shaped clasping portion, and an end surface of the sliding-in end of the power adapter abuts against the hanging plate.

16. The electric appliance of claim 10, wherein an end of the power adapter slides into and being limited into the accommodating space and is press-fitted with the strip-shaped clasping portion, and an end surface of the sliding-in end of the power adapter abuts against the hanging plate.

17. The electric appliance of claim 13, wherein the power adapter is provided with slots on its surfaces facing toward the side plate, and the strip-shaped clasping portion is engaged with into the corresponding slot.

18. The electric appliance of claim 7, wherein the electric appliance is the one selected from a group consisting of a security camera, a set top box, a router, a light bar, a liquid crystal display, a laptop, a massage chair, an electric bed and a medical bed.

19. The electric appliance of claim 13, wherein the electric appliance is the one selected from a group consisting of a security camera, a set top box, a router, a light bar, a liquid crystal display, a laptop, a massage chair, an electric bed and a medical bed.

20. The electric appliance of claim 17, wherein the electric appliance is the one selected from a group consisting of a security camera, a set top box, a router, a light bar, a liquid crystal display, a laptop, a massage chair, an electric bed and a medical bed.
